(19) United States
(12) Patent Application Publication
(10) Pub. No.: US 2006/0226485 A1
(43) Pub. Date: Oct. 12, 2006

(54) Semiconductor device

(76) Inventor: Yoshikazu Arakawa, Miyagi (JP)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/374,172

(22) Filed: Mar. 14, 2006

(30) Foreign Application Priority Data
Apr. 7, 2005 (JP) 2005-110498

(51) Int. Cl. H01L 27/12

(52) U.S. Cl. 257/347

(57) ABSTRACT

A semiconductor element is configured to prevent deterioration thereof due to an electrical charge occurring at a top surface/bottom surface of a support substrate during a plasma process in manufacturing a semiconductor device using an SOI substrate. The semiconductor device includes a MOS transistor formed on an SOI layer of the SOI substrate; a wiring pattern which is formed on an interlayer insulating film covering the SOI layer and is connected to a gate electrode or a diffusion layer of the MOS transistor through a via; and a protection circuit which is connected between the support substrate of the SOI substrate and the wiring pattern and which, when the amount of charges generated with respect to the gate electrode during a plasma process of forming the wiring pattern exceeds a predetermined value, discharges the charges toward the support substrate or blocks the charges. For example, the protection circuit includes a series circuit of a PN junction diode and an NP junction diode each having a breakdown voltage value corresponding to the predetermined value.

### BACKGROUND OF THE INVENTION

1. Field of the Invention

The present invention relates to a semiconductor device using an SOI (silicon-on-insulator) substrate, and in particular, to a technique for preventing deterioration of a semiconductor element caused by the electric charge occurring at a top surface/bottom surface of a support substrate during a plasma process in manufacturing the semiconductor device.

2. Description of the Related Art

A technique for preventing deterioration of a semiconductor element in a process (plasma process) of manufacturing a conventional semiconductor device using an SOI substrate is disclosed in Japanese Patent Kokai No. 2003-133559 (patent document 1), FIG. 2, for example.

FIGS. 1 to 3 are views schematically illustrating the configuration of a conventional semiconductor device using an SOI substrate. Specifically, FIG. 1 is a longitudinal sectional view illustrating the configuration of the semiconductor device and shows that a gate oxide film is damaged due to a supplied antenna current, FIG. 2 is a view illustrating the structure of a protection circuit for preventing the gate oxide film from being damaged, and FIG. 3 is a circuit diagram of the semiconductor device shown in FIG. 2.

The conventional semiconductor device shown in FIG. 1 has, for example, a two-layered wiring structure. In the semiconductor device, for example, MOS field effect transistors (hereinafter, referred to as ‘MOS transistor’) 20-1 and 20-2 serving as semiconductor elements are formed on an SOI substrate 10. The SOI substrate 10 includes a support substrate 11 made of, for example, a p-type silicon (Si), an insulating film (for example, a BOX layer made of silicon dioxide (SiO₂)) 12 formed on the support substrate 11, and an SOI layer 13, which is a silicon layer, formed on the insulating film 12. Within the SOI layer 13, a plural pairs of impurity diffusion regions (for example, a source region 21 and a drain region 22) are formed, and the source region 21 and the drain region 22 are electrically separated from each other by an element separation layer 25. A gate electrode 24 is formed on between each pairs of the source region 21 and the drain region 22 with a gate insulating film (for example, a gate oxide film) 23, and thus each pairs of the source region 21 and the drain region 22 and the gate electrode 24 form each of the MOS transistors 20-1 and 20-2.

On the SOI layer 13 formed with the MOS transistors 20-1 and 20-2, a first interlayer insulating film 30 is formed so as to cover the MOS transistors 20-1 and 20-2. The interlayer insulating film 30 is formed with a plurality of via holes (hereinafter, referred to as ‘via’) 31 vertically penetrating the interlayer insulating film 30. On the interlayer insulating film 30, a first wiring pattern 32 connected to the vias 31 is formed. The wiring pattern 32 is formed, for example, by forming a wiring layer on the entire surface of the interlayer insulating film 30, then forming a resist pattern on the wiring layer, and then etching the wiring layer by using a plasma etching method with the resist pattern as a mask. On the interlayer insulating film 30 and the wiring pattern 32, a second interlayer insulating film 33 is formed so as to cover the interlayer insulating film 30 and the wiring pattern 32. The second interlayer insulating film 33 is formed with a plurality of vias 34 in the same manner as in the first interlayer insulating film 30, and a second wiring pattern 35 connected to the vias 34 is formed on the interlayer insulating film 33.

In a process of manufacturing the semiconductor device having the configuration described above, a plasma process, such as a plasma etching process, a sputtering process, or a plasma CVD (chemical vapor deposition) process, is used. When the wiring patterns 32 and 35 or the vias 31 and 34, which can serve as an antenna, are exposed to the plasma, the wiring patterns 32 and 35 or the vias 31 and 34, which are not connected to the support substrate 11 (which are not grounded) and are in floating states, are stored with charges due to the plasma. If the charges flow through the gate electrodes 24, the source regions 21, or the drain regions 22 of the MOS transistors 20-1 and 20-2 and the voltage generated by the charges is larger than the withstand voltage of the MOS transistors 20-1 and 20-2, a current flows through the gate oxide film 23, and accordingly, the gate oxide film 23 is damaged. As a result, the MOS transistors 20-1 and 20-2 are damaged or the functions of the MOS transistors 20-1 and 20-2 are deteriorated.

In particular, in a case of the semiconductor device using the SOI substrate 10, since the SOI layer 13 forming the MOS transistors 20-1 and 20-2 is completely insulated from the support substrate 11 due to the BOX layer 12, all of the wiring patterns 32 and 35 become in floating states, and accordingly, charges noticeably increases.

In order to avoid the above-described phenomenon, for example as shown in FIG. 2 of the patent document 1, when wiring patterns 32, 35, . . . or vias 31, 34, . . . respectively connected to a plurality of MOS transistors 20-1, 20-2, . . . are formed, a semiconductor device shown in FIG. 2 of JP-A-2003-133559 includes a protective NP junction diode 26, which makes excessive charges flow through a support substrate 11, provided within a SOI layer 13 in the vicinity of a MOS transistor exceeding a predetermined value if the ratio between an area of each of the wiring patterns 32, 35, . . . or each of the vias 31, 34, . . . and a gate area of each of the MOS transistors 20-1, 20-2, . . . exceeds the predetermined value. For example, each of the NP junction diodes 26 is connected between the wiring pattern 32, which is connected to the gate electrode 24 of the MOS transistor 20-1, and a P⁺-type contact region 14 formed within the support substrate 11 through the via 31.

As shown in FIG. 3, for example, when excessive positive (+) charges are supplied to the wiring pattern 35, serving as an antenna, by the plasma during the plasma process, the NP junction diode 26 breaks down by the reverse biased voltage to be turned on, and thus the supplied positive charges are discharged toward the support substrate 11 through the NP junction diode 26. Accordingly, since the excessive positive charges are not supplied to the gate electrode 24 of the MOS transistor 20-1, it is possible to prevent the MOS transistor 20-1 from being damaged or deteriorated.

### SUMMARY OF THE INVENTION

Since the protective diode 26 is provided in the conventional semiconductor device shown in FIG. 2, for example, when a forward biased voltage with respect to the diode 26 is applied to a bottom surface of the support substrate 11 during the plasma process, the current flow is the bottom surface of the support substrate 11→the via 31→the wiring pattern 32→the via 31→the diode 26→the via 31→the wiring pattern 32→the via 31→the gate electrode 24 of the MOS transistor 20-1 and the gate oxide film 23 is damaged when the voltage exceeds the predetermined value. As a result, the MOS transistor 20-1 cannot serve as a semiconductor element.

Hereinafter, the above technical issues will be described in detail with reference to FIGS. 4, 5, 6A, and 6B.

FIGS. 4, 5, 6A, and 6B are views for explaining the technical issues of the related art. Here, FIGS. 4 and 5 illustrate charging states due to electrostatic chuck (hereinafter, referred to as ‘ESC chuck’). Specifically, FIG. 4 is an explanatory view illustrating a monopolar ESC chuck 40 for suctioning and holding the support substrate 11 in the plasma process, and FIG. 5 is an explanatory view illustrating a bipolar ESC chuck 41 used in the plasma process. FIGS. 6A and 6B are views illustrating the potential variation of a wiring layer in etching the wiring layer. Specifically, FIG. 6A is an explanatory view illustrating the potential variation of the wiring layer during the process of etching the wiring layer when the monopolar ESC chuck 40 is used, and FIG. 6B is an explanatory view illustrating the potential variation of the wiring layer immediately after the wiring layer is etched (that is, when the wiring layer is separated by the etching process to becomes a wiring pattern) when the monopolar ESC chuck 40 is used.

In FIGS. 4 and 5, as a plasma CVD apparatus or a dry etching apparatus used in the plasma process, the monopolar ESC chuck 40 or the bipolar ESC chuck 41 is used to support the support substrate 11 which is in a wafer state before being separated. When a high voltage in the range of 800 to 2000 V is applied to the ESC chucks 40 and 41, the ESC chucks 40 and 41 generate electrostatic charges so as to suction the support substrate 11, which is in a wafer state, with the electrostatic charges. At this time, dielectric charges are generated on the support substrate 11 by the electrostatic charges. The monopolar ESC chuck 40 negative-charges the bottom surface of the support substrate 11, and thus a surface of the monopolar ESC chuck 40 is positive-charged. The bipolar ESC chuck 41 has a positive chuck portion 41-1, to which a positive high voltage in the range of 800 to 2000 V is applied, and a negative ESC chuck portion 41-2, to which a negative high voltage in the range of −2000 to −800 V is applied. Accordingly, a bottom surface of the support substrate 11 being in contact with the positive chuck portion 41-1 is negative-charged, and as a result, a surface of the positive chuck portion 41-1 is positive-charged. On the other hand, a bottom surface of the support substrate 11 being in contact with the negative chuck portion 41-2 is positive-charged, and as a result, a surface of the negative chuck portion 41-2 is negative-charged.

Next, the potential variation of a wiring layer 36 in etching the wiring layer 36 when the monopolar ESC chuck 40 is used will be described with reference to FIGS. 6A and 6B.

While the wiring layer 36 shown in FIG. 6A is etched, the positive charges, which exist on the surface of the support substrate 11 and generated by the ESC chuck 40, pass through a forward-connected diode 26 and then pass through each of the gate electrodes 24 of all of the connected MOS transistors 20-1, 20-2, 20-3, . . . through the vias 31 and 34 and the wiring layer 36. While the wiring layer 36 is etched, the applied positive charges are uniformly distributed on all of the wiring layers 36 connected through the vias 31 and 34. Accordingly, the effect of the applied positive charges on one of the MOS transistors 20-1, . . . is small.

Thereafter, when the wiring patterns 32 and 35 are formed by separation of the wiring layer 36 and the etching process is completed as shown in FIG. 6B, all of the charges existing on the surface of the support substrate 11 are supplied to the gate electrode 24 of the MOS transistor 20-1 having a small number of diodes 26 connected thereto. Then, a pass-through current flows through the gate oxide film 23→the source region 21 or drain region 22 of the SOI layer 13→another circuit, and as a result, the gate oxide film 23 of the MOS transistor 20-1 is damaged by the pass-through current.

In contrast, even though it is considered that no problem occurs in a bottom surface portion of the support substrate 11 being in contact with the negative ESC chuck portion 41-2 when the bipolar ESC chuck 41 is used, the above-described problem occurs in a bottom surface portion of the support substrate 11 being in contact with the positive ESC chuck portion 41-1.

In order to solve the above-mentioned problems, according to an aspect of the invention, a semiconductor device includes: a semiconductor element (for example, a field effect transistor) having a diffusion layer and a gate electrode with a gate insulating film interposed therebetween, the diffusion layer being formed within a silicon layer of an SOI substrate in which the silicon layer is formed on a support substrate with an insulating film interposed therebetween; a wiring pattern which is formed on an interlayer insulating film covering the silicon layer and is connected to the gate electrode or the diffusion layer of the semiconductor element through a via penetrating the interlayer insulating film; and a protection circuit which is connected between the support substrate and the wiring pattern connected to the gate electrode or the diffusion layer and which, when the amount of charges generated with respect to the gate electrode during a plasma process of forming the wiring pattern exceeds a predetermined value, discharges the charges toward the support substrate or blocks the charges.

Further, according to another aspect of the invention, a semiconductor device includes: a semiconductor element having a diffusion layer and a gate electrode with a gate insulating film interposed therebetween, the diffusion layer being formed within a silicon layer of an SOI substrate in which the silicon layer is formed on a support substrate with an insulating film interposed therebetween; a wiring pattern which is formed on an interlayer insulating film covering the silicon layer and is connected to the gate electrode or the diffusion layer of the semiconductor element through a first via penetrating the interlayer insulating film; a protection circuit which is connected between the support substrate and the wiring pattern connected to the gate electrode or the diffusion layer and which, when the amount of charges generated with respect to the gate electrode during a plasma process of forming the wiring pattern exceeds a predetermined value, discharges the charges toward the support substrate; and a dummy conductive pattern which is formed on the interlayer insulating film and is connected to the support substrate through a second via penetrating the interlayer insulating film.

In the semiconductor device according to the first aspect of the invention, since the protection circuit is provided, even though, for example, an ESC chuck voltage is applied to a bottom surface of the support substrate during the plasma process, it is possible to prevent the applied voltage from being applied to the gate electrode of the semiconductor element. In addition, even though an excessive plasma charge voltage is applied to the wiring pattern or the like, it is possible to discharge the applied voltage toward the support substrate. As a result, it is possible to reliably prevent the gate insulating film from being damaged due to both the voltage applied to the bottom surface of the support substrate and the plasma charge voltage.

Further, in the semiconductor device according to the second aspect of the invention, since the dummy conductive pattern is provided, it is possible to reduce a current flowing from the bottom surface of the support substrate toward the protection circuit during the plasma process. As a result, it is possible to prevent the gate insulating film from being damaged.

### BRIEF DESCRIPTION OF THE DRAWINGS

FIG. 1 is a view schematically illustrating the configuration of a conventional semiconductor device using an SOI substrate;

FIG. 2 is a view schematically illustrating the configuration of a conventional semiconductor device using an SOI substrate;

FIG. 3 is a circuit diagram illustrating the semiconductor device shown in FIG. 2;

FIG. 4 is a view illustrating the charging state caused by an electrostatic chuck so as to explain a technical issue of the related art;

FIG. 5 is a view illustrating the charging state caused by an electrostatic chuck so as to explain a technical issue of the related art;

FIG. 6A is a view illustrating the potential variation of a wiring layer in etching the wiring layer;

FIG. 6B is a view illustrating the potential variation of a wiring layer in etching the wiring layer;

FIG. 7 is a longitudinal sectional view schematically illustrating the configuration of a semiconductor device using an SOI substrate according to a first embodiment of the invention;

FIG. 8 is a plan view illustrating the configuration of the semiconductor device using the SOI substrate according to the first embodiment of the invention;

FIG. 9 is a circuit diagram of the semiconductor device using the SOI substrate according to the first embodiment of the invention;

FIG. 10 is a wave form chart illustrating an operation of the semiconductor device using the SOI substrate according to the first embodiment of the invention;

FIG. 11 is a longitudinal sectional view schematically illustrating the configuration of a semiconductor device using an SOI substrate according to a second embodiment of the invention;

FIG. 12 is a circuit diagram of the semiconductor device using the SOI substrate according to the second embodiment of the invention;

FIG. 13 is a longitudinal sectional view schematically illustrating the configuration of a semiconductor device using an SOI substrate according to a third embodiment of the invention;

FIG. 14 is a circuit diagram of the semiconductor device using the SOI substrate according to the third embodiment of the invention;

FIG. 15 is a longitudinal sectional view schematically illustrating the configuration of a semiconductor device using an SOI substrate according to a fourth embodiment of the invention;

FIG. 16 is a plan view illustrating the configuration of the semiconductor device using the SOI substrate according to the fourth embodiment of the invention;

FIG. 17 is a circuit diagram of the semiconductor device using the SOI substrate according to the fourth embodiment of the invention;

FIG. 18 is a longitudinal sectional view schematically illustrating the configuration of a semiconductor device using an SOI substrate according to a fifth embodiment of the invention;

FIG. 19 is a plan view illustrating the configuration of the semiconductor device using the SOI substrate according to the fifth embodiment of the invention;

FIG. 20 is a circuit diagram of the semiconductor device using the SOI substrate according to the fifth embodiment of the invention;

FIG. 21 is a plan view schematically illustrating main parts of the semiconductor device using an SOI substrate according to a sixth embodiment of the invention;

FIG. 22 is a cross-sectional view taken along the line XXII-XXII of FIG. 21; and

FIG. 23 is a circuit diagram of the semiconductor device using the SOI substrate according to the sixth embodiment of the invention.

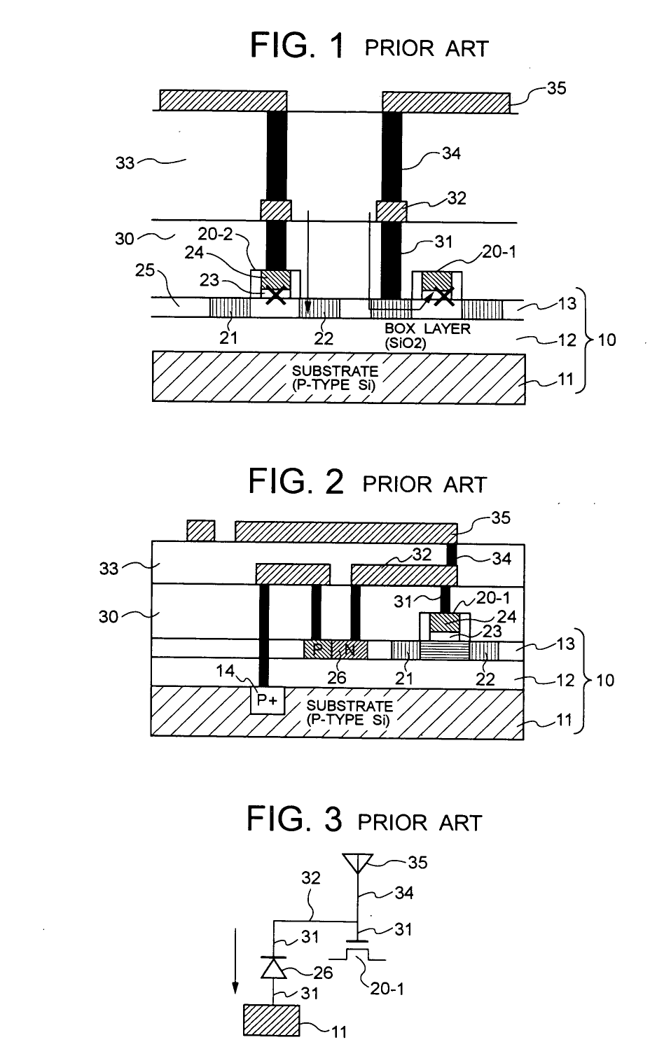

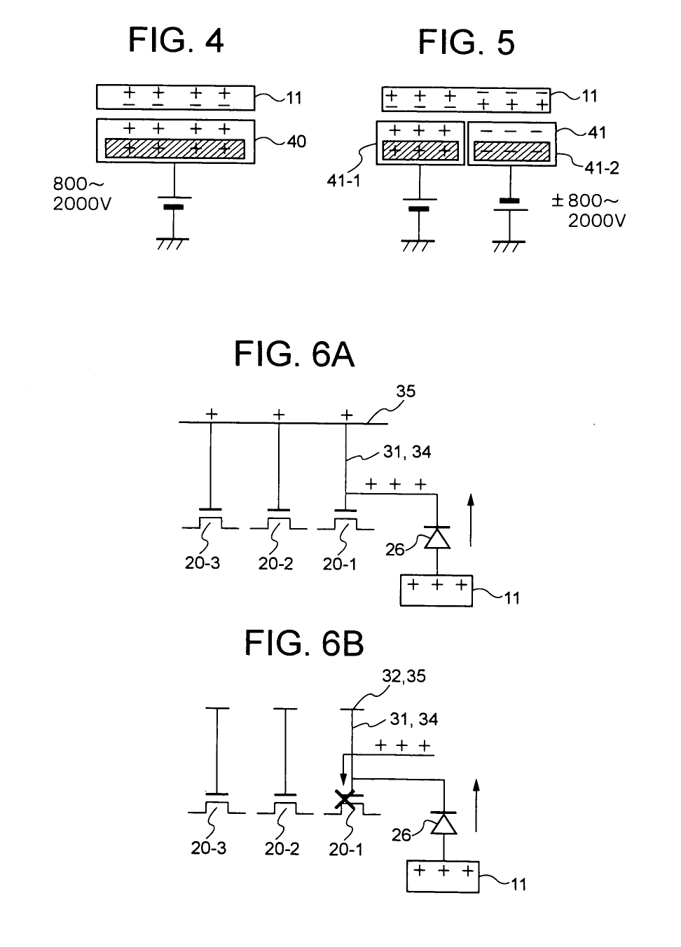

### DETAILED DESCRIPTION OF THE INVENTION

(Configuration of First Embodiment)

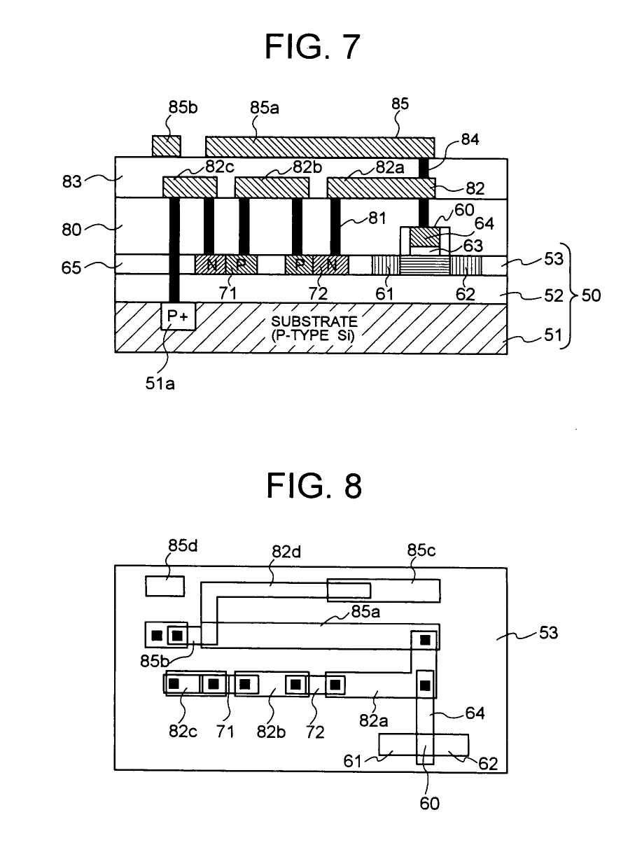

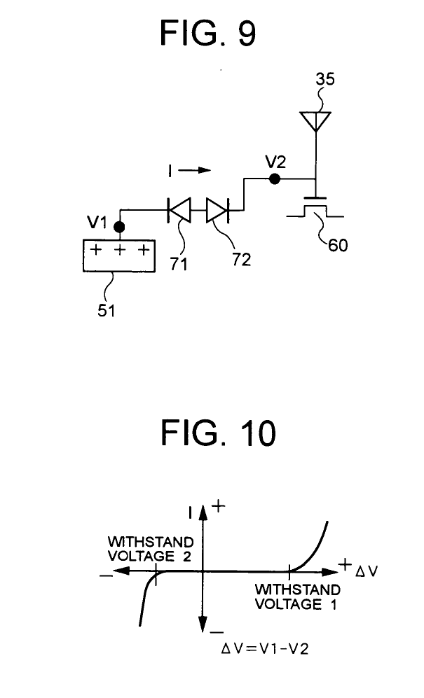

FIGS. 7 to 10 are views schematically illustrating the configuration of a semiconductor device using an SOI substrate according to a first embodiment of the invention. Specifically, FIG. 7 is a longitudinal sectional view illustrating the configuration of the semiconductor device, FIG. 8 is a top plan view illustrating the configuration of the semiconductor device, FIG. 9 is a circuit diagram of the semiconductor device, and FIG. 10 is a wave form chart illustrating an operation of the semiconductor device.

The semiconductor device according to the first embodiment shown in FIGS. 7 and 8 has, for example, a two-layered wiring structure. In the semiconductor device, a semiconductor element (for example, MOS transistor) 60 and a protection circuit (for example, a series circuit composed of a NP junction diode 72 and an PN junction diode 71) for protecting the semiconductor element 60 are formed on the SOI substrate 50. The SOI substrate 50 includes a support substrate 51 made of, for example, a p-type Si, an insulating film (for example, a BOX layer made of SiO₂) 52 formed on the support substrate 51, and an Si layer (for example, a p-type SOI layer) 53 formed on the insulating film 52. A P⁺-type contact region 51a is formed within the support substrate 51. In addition, the contact region 51a may not be formed. Within the SOI layer 53, an impurity diffusion layer (for example, a source region 61 and a drain region 62) that form the MOS transistor 60, the PN junction diode 71 composed of a p-type diffusion region and an N-type diffusion region, and the NP junction diode 72 composed of the N-type diffusion region and the p-type diffusion region are formed, and the impurity diffusion layer, the PN junction diode 71, and the NP junction diode 72 are electrically separated from each other by an element separation layer 53. A gate electrode 64 is formed on the region between the source region 61 and the drain region 62 with a gate insulating film (for example, a gate oxide film) 63 interposed therebetween, and thus the source region 61, the drain region 62, and the gate electrode 64 form the MOS transistor 60.

On the SOI layer 53 formed with the MOS transistor 60, the PN junction diode 71, and the NP junction diode 72, a first interlayer insulating film 80 made of, for example, SiO₂, is formed so as to cover the MOS transistor 60, the PN junction diode 71, and the NP junction diode 72. The interlayer insulating film 80 is formed with a plurality of vias 81, each of the vias 81 vertically passing through the interlayer insulating film 80. On the interlayer insulating film 80, a first wiring pattern 82, which is connected to the vias 81 and composed of a wiring layer made of, for example, metal or polysilicon, is formed. The wiring pattern 82 includes, for example, a wiring portion 82a for connecting the gate electrode 64 of the MOS transistor 60 and the NP junction diode 72 through the vias 81, a wiring portion 82b for connecting the PN junction diode 71 and the NP junction diode 72 in series through the vias 81, a wiring portion 82c for connecting the PN junction diode 71 and the contact region 51a through the vias 81, and a wiring portion 82d.

On the interlayer insulating film 80 and the wiring pattern 82, a second interlayer insulating film 83 made of, for example, SiO₂, is formed so as to cover the interlayer insulating film 80 and the wiring pattern 82. The second interlayer insulating film 83 is formed with a plurality of vias 84 in the same manner as in the first interlayer insulating film 80, and a second wiring pattern 85, which is connected to the vias 84 and composed of a wiring layer made of, for example, metal or polysilicon, is formed on the interlayer insulating film 83. The wiring pattern 85 includes, for example, a wiring portion 85a connected to the wiring portion 82a and the wiring portion 82d through the vias 84, a wiring portion 85b connected to the wiring portion 82d and the wiring portion 85a through the vias 84, a wiring portion 85c connected to the wiring portion 82d through the vias 84, and a wiring portion 85d.

Example of a Process of Manufacturing the Semiconductor Device According to the First Embodiment

The semiconductor device according to the first embodiment is manufactured by, for example, following manufacturing processes (1) to (7).

(1) Process of Preparing the SOI Substrate 50

The SOI substrate 50 having a wafer shape before being separated is prepared.

(2) Process of Forming a Semiconductor Element

By using a photolithographic technique, a photoresist is coated on the SOI layer 53, and then the photoresist is exposed and developed so as to form a resist pattern. Impurity ions are implanted into a portion of the SOI layer 53, which is designed beforehand, by using the resist pattern as a mask, thereby forming the NP junction diode 72. An oxide film is formed on the SOI layer 53, an electrode layer made of, for example, polysilicon is formed thereon, a resist pattern is formed on the electrode layer by using the photolithographic technique, the electrode layer and the oxide layer are etched by using the resist pattern as a mask, and the gate oxide film 63 and the gate electrode 64 are selectively formed on between the source region 61 and the drain region 62. Then, impurity ions are implanted into the SOI layer 53 by using the gate electrode 64 as a mask, thereby forming the source region 61 and the drain region 62. Thus, the MOS transistor 60 composed of the source region 61, the drain region 62, the gate oxide film 63, and the gate electrode 64 is formed. The source region 61, the drain region 62, the PN junction diode 71, and the NP junction diode 72 are electrically separated from each other by the element separation layer 53 which is formed by a predetermined process and made of, for example, SiO₂.

(3) Process of Forming a First Interlayer Insulating Film

The first interlayer insulating film 80 is formed on the SOI layer 53 formed with the MOS transistor 60, the PN junction diode 71, and the NP junction diode 72 by using a plasma CVD method.

(4) Process of Forming a First Wiring Pattern

A resist pattern is formed on the interlayer insulating film 80 by using the photolithographic technique, and by using the resist pattern as a mask, a plurality of openings for the vias 81 are formed by using a plasma etching method. P⁺-type impurity ions are implanted through an opening, among the plurality of openings, reaching the support substrate 51 so as to form the contact region 51a within the support substrate 51.

A wiring layer made of, for example, metal is formed on the entire surface of the interlayer insulating film 80 by using a plasma sputtering method, or a wiring layer made of, for example, polysilicon is formed on the entire surface of the interlayer insulating film 80 by using a CVD method (wiring layer forming process). At this time, the wiring layer is embedded in the plurality of openings so as to form the vias 81. In a subsequent plasma etching process, a resist pattern is selectively formed on the wiring layer by using the photolithographic technique (resist pattern forming process), the wiring layer is separated, by using a plasma etching method in which the resist pattern is used as a mask, so as to form the first wiring pattern 82 (wiring pattern forming process), and residue is removed by overetching (residue removing process). Then, an oxygen (O₂) ashing process is performed by an ashing device so as to remove unnecessary resist pattern (ashing process).

(5) Process of Forming a Second Interlayer Insulating Film

The second interlayer insulating film 83 made of, for example, SiO₂ is formed on the first interlayer insulating film 80 on which the first wiring pattern 82 is formed by using a plasma CVD method.

(6) Process of Forming a Second Wiring Pattern

In the same manner as the process of forming the first wiring pattern, the second interlayer insulating film 83 is formed with a plurality of openings for the vias 84, a wiring layer made of, for example, metal or polysilicon is formed on the entire surface of the second interlayer insulating film 83, the wiring layer is separated by the plasma etching method so as to form the second wiring pattern 85 (wiring pattern forming process), residue is removed by an overetching process (residue removing process). Then, unnecessary resist pattern is removed by the O₂ ashing process (ashing process).

(7) Final Process

The manufacturing process is completed, for example, by covering the second wiring pattern 85 with a protective film made of, for example, SiO₂.

In the manufacturing process described above, during the residue removing process of forming the wiring patterns 82 and 85 and the ashing process, the wiring patterns 82 and 85 act as an antenna so as to collect charges during a plasma process. As a result, there is a possibility that the charges damage the gate oxide film 63 of the MOS transistor 60. For this reason, in order for the excessive charges not to damage the gate oxide film 63, a layout design in which the antenna ratio of wiring lines is restricted is made by using methods such as following (a) and (b).

(a) Calculation on the Antenna Ratio A1 of the First Wiring Pattern 82

The area of the gate oxide film 63 of the MOS transistor 60 is assumed to be G1. When the wiring layer of the first wiring pattern 82 is etched/ashed, the antenna (wiring) area M1 connected to the MOS transistor 60 is as follows.

Antenna area M1=wiring portions (82a+82b+82c)

(Here, the wiring portion 82d is not included.) Antenna ratio A1=Antenna area M1/gate area G1=(82a+82b+82c)/G1

(b) Calculation on the Antenna Ratio A1 of the Second Wiring Pattern 85

Antenna area M2=wiring portions (85a+85b+85c)

(Here, the wiring portion 85d is not included.)

Antenna ratio A2=Antenna area M2/gate area G2=(85a+85b+85c)/G2

Even though the limited value of each of the antenna ratios A1 and A2 varies according to the film thickness or the withstand voltage of the gate oxide film 63, in a case in which the antenna ratio exceeds about 400 in, for example, a typical 180 nm logic device, a protection circuit composed of the PN junction diode 71 and the NP junction diode 72 is provided for the MOS transistor 60 corresponding to a portion where the antenna ratio exceeds about 400. A connection is made through the gate electrode 64 of the MOS transistor 60→the wiring portion 82a→the NP junction diode 72→the wiring portion 82b→the PN junction diode 71→the wiring portion 82c→the support substrate 51, and the diodes 71 and 72 having different polarities are connected in series to each other.

Operation of the Semiconductor Device According to the First Embodiment

In the semiconductor device according to the first embodiment, the ratio between a gate area of a transistor and a total area of the wiring patterns 82 and 85 connected to the MOS transistor 60 is calculated beforehand, and when the antenna ratios A1 and A2 exceed a predetermined value, a protection circuit composed of the diodes 71 and 72 is provided. Thereby, as shown in FIGS. 8 and 9, when a voltage applied to a bottom surface of the support substrate 51 by an ESC chuck 40 is lower than a withstand voltage 1 of the diode 71, the diode 71 is turned off by a reverse bias and thus a current does not flow through the gate electrode 64 of the MOS transistor 60. Accordingly, the gate oxide film 63 is not damaged. In addition, when a voltage applied to the wiring pattern 85 by plasma charge is higher than a withstand voltage 2 of the diode 72, the diode 72 breaks down. As a result, a current flows through the wiring pattern 85→via 84→the wiring portion 82a→the diode 72→the wiring portion 82b→the diode 71→the wiring portion 82c→the contact region 51a→the support substrate 51, and thus the gate oxide film 63 of the MOS transistor 60 is not damaged.

Effects of the First Embodiment

In the first embodiment, by setting the withstand voltage 1 of the diode 71 to be sufficiently higher (for example, −2000 V) than an ESC chuck voltage and setting the withstand voltage 2 of the diode 72 to be higher (for example, 5 V) than an operation voltage of a circuit (for example, the MOS transistor 60) and lower (for example, 12 V) than a plasma charge voltage, it is possible to prevent the gate oxide film 63 from being damaged due to the voltage applied to the bottom surface of the support substrate 51 and the plasma charge voltage.

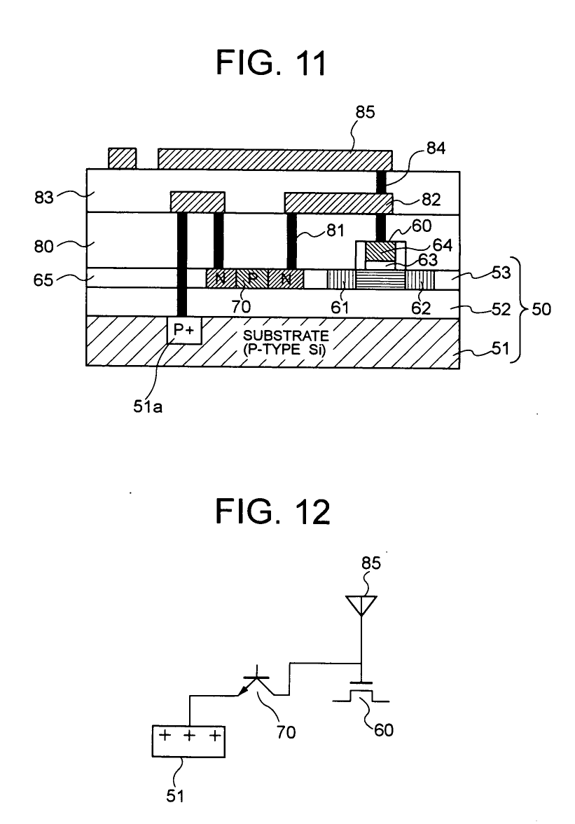

FIGS. 11 and 12 are views schematically illustrating the configuration of a semiconductor device using an SOI substrate according to a second embodiment of the invention. Specifically, FIG. 11 is a longitudinal sectional view illustrating the configuration of the semiconductor device, and FIG. 12 is a circuit diagram of the semiconductor device. In FIGS. 11 and 12, the same elements as in FIG. 7 showing the first embodiment are denoted by the same reference numerals.

The semiconductor device according to the second embodiment has, for example, a two-layered wiring structure in the same manner as in the semiconductor device according to the first embodiment, except that an NPN junction device 70 is provided instead of the PN junction diode 71 and the NP junction diode 72.

The semiconductor device according to the second embodiment is manufactured in the same manner as the semiconductor device according to the first embodiment. That is, the ratio between a gate area of a transistor and a total area of the wiring patterns 82 and 85 connected to the MOS transistor 60 is calculated beforehand, and when the antenna ratios A1 and A2 exceed a predetermined value, the NPN junction device 70 is provided. Thereby, it is possible to obtain approximately the same operation and effects as in the first embodiment. In particular, in the second embodiment, since the NPN junction device 70 is provided instead of the PN junction diode 71 and the NP junction diode 72 in the first embodiment, it is possible to realize the semiconductor device having an area smaller than in the first embodiment. In addition, even when a PNP junction device is used instead of the NPN junction device 70, almost the same effects can be obtained.

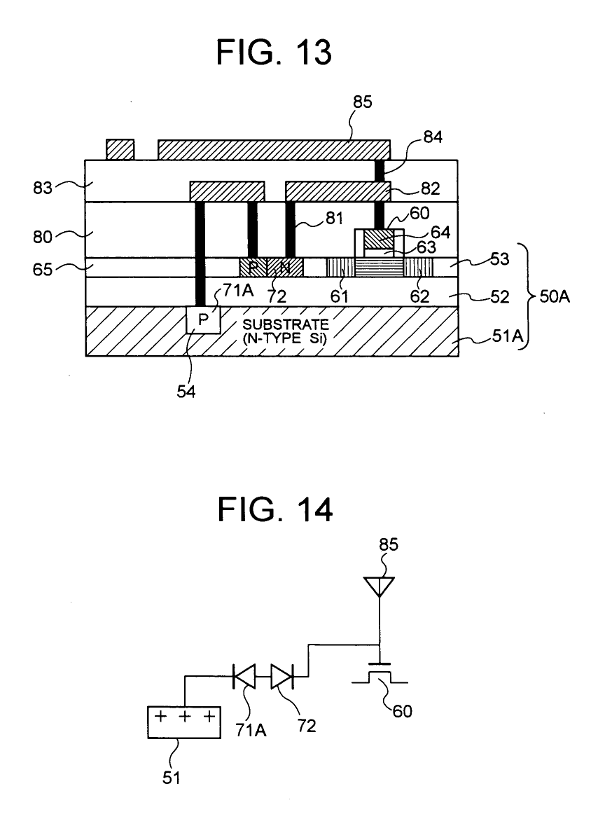

FIGS. 13 and 14 are views schematically illustrating the configuration of a semiconductor device using an SOI substrate according to a third embodiment of the invention. Specifically, FIG. 13 is a longitudinal sectional view illustrating the configuration of the semiconductor device, and FIG. 14 is a circuit diagram of the semiconductor device. In FIGS. 13 and 14, the same elements as in FIGS. 7 and 9 showing the first embodiment are denoted by the same reference numerals.

The semiconductor device according to the third embodiment has, for example, a two-layered wiring structure in the same manner as in the semiconductor device according to the first embodiment, except that a PN junction diode 71A having a vertical structure is provided in an SOI substrate 50A instead of the PN junction diode 71 formed on the support substrate 51 in the first embodiment. The PN junction diode 71A having the vertical structure is composed of a p-type diffusion layer 54 and an N-type Si substrate, the p-type diffusion layer 54 being formed on a part of a support substrate 51A which is, for example, an N-type Si substrate. In addition, the PN junction diode 71A is connected in series to the NP junction diode 72 through the vias 81 and the wiring portion 82b.

In the semiconductor device according to the second embodiment, it is possible to obtain approximately the same operation and effects as in the first embodiment. In particular, in the third embodiment, since the PN junction diode 71A at the support substrate 51A side has a vertical structure, it is possible to realize the semiconductor device having an area smaller than in the first embodiment. In addition, even when a PN junction diode is provided at the MOS transistor 60 side and an NP junction diode having a vertical structure is provided at the support substrate 51A, almost the same effects can be obtained.

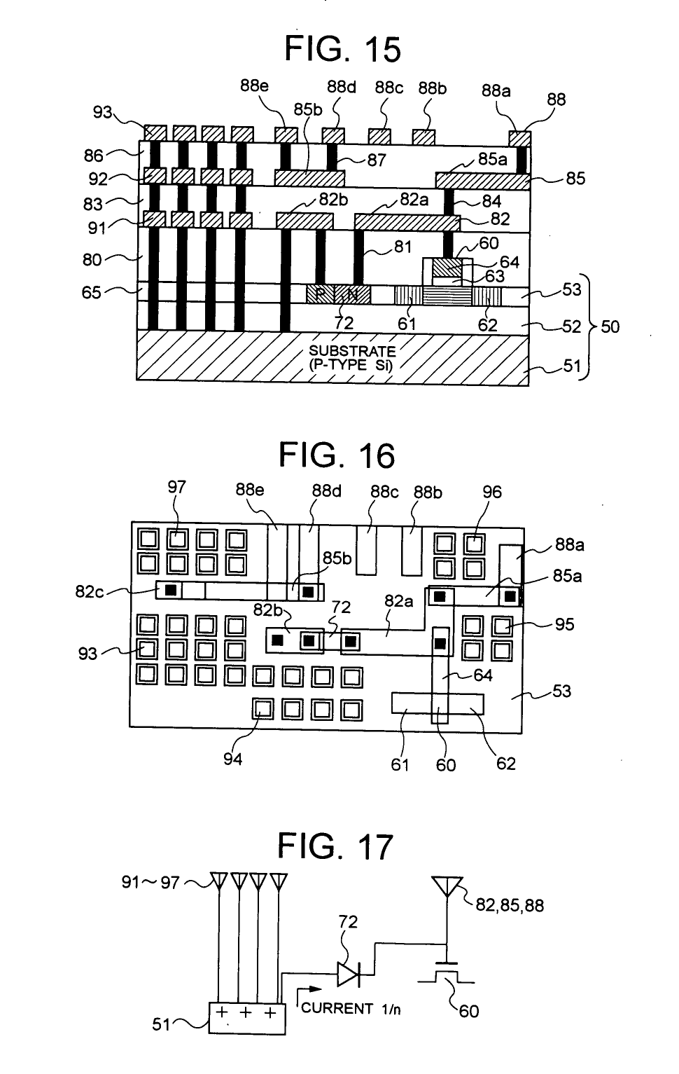

FIGS. 15 to 17 are views schematically illustrating the configuration of a semiconductor device using an SOI substrate according to a fourth embodiment of the invention. Specifically, FIG. 15 is a longitudinal sectional view illustrating the configuration of the semiconductor device, FIG. 16 is a top plan view illustrating the configuration of the semiconductor device, and FIG. 17 is a circuit diagram of the semiconductor device. In FIGS. 15 to 17, the same elements as in FIGS. 7 and 9 showing the first embodiment are denoted by the same reference numerals.

The semiconductor device according to the fourth embodiment has, for example, a three-layered wiring structure, and is different from the semiconductor device according to the first embodiment in that, instead of the protection element (for example, a PN junction diode) 71 in the first embodiment, dummy conductive patterns 91 to 97, which are not related to a circuit, are provided and the dummy conductive patterns 91 to 97 are connected to a support substrate 51 through vias 81, 84, and 87.

That is, in order to design a layout of wiring lines, the ratio between a gate area of a transistor and a total area of the wiring patterns 82, 85, and 88 connected to the MOS transistor 60 is calculated beforehand, and when the antenna ratio exceeds a predetermined value, a protection circuit (for example, an NP junction diode) 72 is provided in the vicinity of an SOI substrate 53 formed with the transistor 60 corresponding to a portion where the antenna ratio exceeds the predetermined value. A plurality of vias 81 is formed in a first interlayer insulating film 80 that covers the protection circuit 72. On the interlayer insulating film 80, a first wiring pattern 82 having wiring portions 82a to 82c is formed and a first dummy conductive pattern 91 which is not related to a circuit and includes a plurality of conductive patterns, having rectangular dot shapes, formed on the empty space is also formed.

The wiring pattern 82 is connected to the MOS transistor 60 and the NP junction diode 72 through the vias 81. For example, a gate electrode 64 of the MOS transistor 60 is connected to the support substrate 51 through the via 81, the wiring portion 82a, the via 81, the NP junction diode 72, the via 81, the wiring portion 82b, and the via 81. The vias 81 and the support substrate 51 are directly connected to each other or connected to each other through a contact region in the support substrate 51 (not shown). The first dummy conductive pattern 91 is connected to the support substrate 51 through the plurality of vias 81.

The wiring pattern 82 and the dummy conductive pattern 91 are covered by a second interlayer insulating film 83, and a plurality of vias 84 is formed in the interlayer insulating film 83. On the interlayer insulating film 83, a second wiring pattern 85 having wiring portions 85a and 85b is formed and a second dummy conductive pattern 92 which is not related to a circuit and includes a plurality of conductive patterns, having rectangular dot shapes, formed on the empty space is also formed. The second wiring pattern 85 is connected to the first wiring pattern 82 through the plurality of vias 84, and the second dummy conductive pattern 92 is connected to the first dummy conductive pattern 91 through the plurality of vias 84.

In the same manner, the wiring pattern 85 and the dummy conductive pattern 92 are covered by a third interlayer insulating film 86, and a plurality of vias 87 is formed in the interlayer insulating film 86. On the interlayer insulating film 86, a third wiring pattern 88 having wiring portions 88a to 88e is formed and third dummy conductive patterns 93 to 97 which are not related to a circuit and include a plurality of conductive patterns, having rectangular dot shapes, formed on the empty space are also formed. The third wiring pattern 88 is connected to the second wiring pattern 85 through the plurality of vias 87, and the third dummy conductive patterns 93 to 97 are connected to the second dummy conductive patterns 92 through the plurality of vias 87.

In the fourth embodiment, since the dummy conductive patterns 91 to 97 not related to the circuit are provided and the dummy conductive patterns 91 to 97 are connected to the support substrate 51 through the vias 81, 84, and 87, it is possible to reduce a current supplied to the NP junction diode 72 from a bottom surface of the support substrate 51. When n dummy conductive patterns 91, . . . are provided for one NP junction diode, the charges existing on the bottom surface of the support substrate 51 are divided. For example, assuming that the area of the dummy conductive pattern 91, . . . and the wiring area connected to the NP junction diode 72 is k multiples, a current, which flows through the NP junction diode 72 due to the bottom-surface charges of the support substrate 51 during a wiring line etching process, is reduced to k/n+k, and a current, which flows through the NP junction diode 72 due to the charges existing on the bottom surface of the support substrate 51 during a via etching process, is reduced to 1/n+1.

As such, by connecting the plurality of dummy conductive patterns 91, . . . in series up to the support substrate 51, it is possible to reduce the effect of the charges, which exist on the bottom surface of the support substrate 51, caused by the ESC chuck 40 or the plasma charge during a process of etching each of the wiring layers, a process of etching each of the via layers, and a CVD process for the an interlayer insulating film.

Even though the optimal number n of the dummy conductive patterns 91, . . . is different according to a used manufacturing device or a manufacturing condition, a sufficient protection effect has been obtained by disposing 1000 dummy conductive patterns 91, . . . per 1 mm² in the present embodiment.

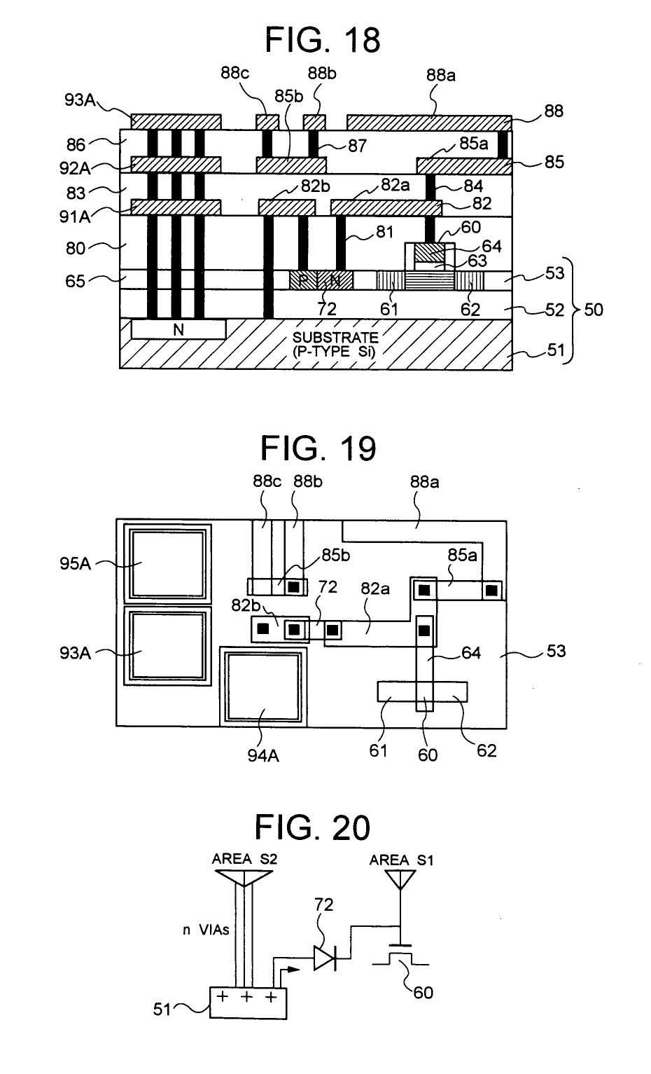

FIGS. 18 to 20 are views schematically illustrating the configuration of a semiconductor device using an SOI substrate according to a fifth embodiment of the invention. Specifically, FIG. 18 is a longitudinal sectional view illustrating the configuration of the semiconductor device, FIG. 19 is a top plan view illustrating the configuration of the semiconductor device, and FIG. 20 is a circuit diagram of the semiconductor device. In FIGS. 18 to 20, the same elements as in FIGS. 15 to 17 showing the fourth embodiment are denoted by the same reference numerals.

The semiconductor device according to the fifth embodiment has, for example, a three-layered wiring structure in the same manner as the semiconductor device according to the fourth embodiment, and is different from the semiconductor device according to the fourth embodiment in that, instead of the dummy conductive patterns 93 to 97 having the rectangular dot shapes in the fourth embodiment, a plurality of plate-shaped dummy conductive patterns 91A to 95A is provided on the respective wiring layers. In addition, referring to FIG. 18, even though the plurality of plate-shaped dummy conductive patterns 91A to 95A is connected to an N-type contact region 51b within a support substrate 51 through vias 81, 84, and 87 of each layer, the contact region 51b may not be provided.

By preparing the plate-shaped dummy conductive patterns 91A to 95A, the ratio k between an area S2 of a dummy conductive pattern and an area S1 of a wiring pattern connected to the NP junction diode 72 and the number n of vias can be adjusted to a proper value. Thereby, a current, which flows through the NP junction diode 72 due to the bottom-surface charges of the support substrate 51 during a wiring line etching process, is reduced to S1/(S1+S2), and a current, which flows through the NP junction diode 72 due to the bottom-surface charges of the support substrate 51 during a via etching process, is reduced to 1/n+1.

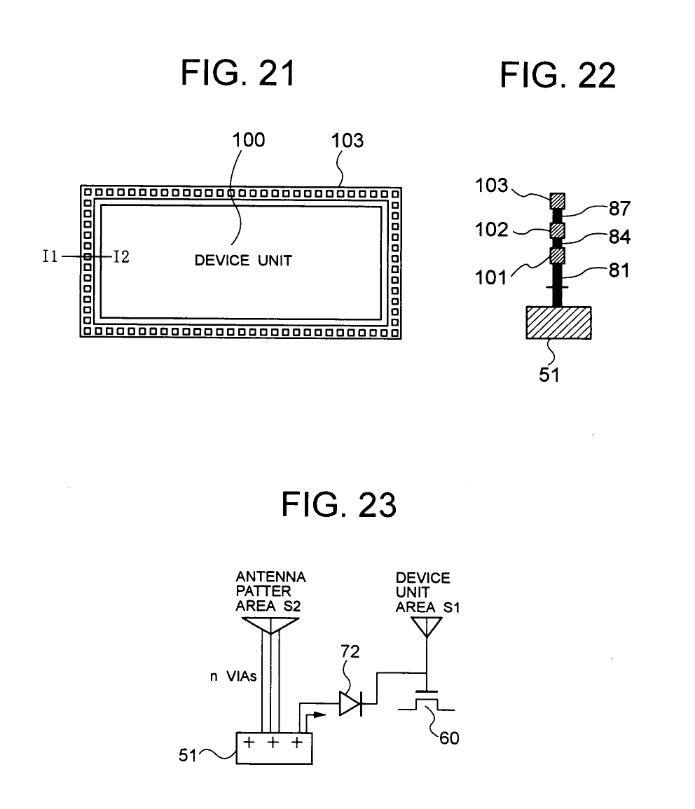

FIGS. 21 to 23 are views schematically illustrating the configuration of a semiconductor device using an SOI substrate according to a sixth embodiment of the invention. Specifically, FIG. 21 is a top plan view illustrating main parts of the semiconductor device, FIG. 22 is a cross-sectional view taken along the line I1-I2 of FIG. 21, and FIG. 23 is a circuit diagram of the semiconductor device. In FIGS. 21 to 23, the same elements as in FIGS. 15 to 17 showing the fourth embodiment are denoted by the same reference numerals.

The semiconductor device according to the sixth embodiment has, for example, a three-layered wiring structure in the same manner as the semiconductor device according to the fourth embodiment, and is different from the semiconductor device according to the fourth embodiment in that, instead of the dummy conductive patterns 93 to 97 having the rectangular dot shapes in the fourth embodiment, a line-shaped dummy conductive patterns 101 to 103 are provided on the respective wiring layers so as to surround the periphery of a device unit 100. The line-shaped conductive patterns 101 to 103 in the respective wiring layers are connected to the support substrate 51 through the vias 81, 84, and 87 (n vias) of each layer.

Assuming that the total area of the device unit 100 in the respective wiring layers is S1 and a pattern area S2 of an antenna composed of the dummy conductive patterns 101 to 103 in the respective wiring layers is S2, in the same manner as in the fifth embodiment, a current, which flows through the NP junction diode 72 due to the bottom-surface charges of the support substrate 51 during a wiring line etching process, is reduced to S1/(S1+S2), and a current, which flows through the NP junction diode 72 due to the bottom-surface charges of the support substrate 51 during a via etching process, is reduced to 1/n+1.

As such, even when the line-shaped dummy conductive patterns 101 to 103 are used, it is possible to obtain almost the same operation and effects as in the fifth embodiment. In particular, by surrounding the periphery of the device unit 100 with the line-shaped dummy conductive patterns 101 to 103, the distribution of top-surface/bottom-surface charges of the support substrate 51 becomes uniform, and accordingly, it is possible to achieve the maximal dummy effects.

Further, the invention is not limited to the first to sixth embodiments. For example, the semiconductor device may be a transistor other than the MOS transistor. In addition, in the semiconductor device, the number of wiring layers, a cross-sectional structure, a planar structure seen from above, a forming material, and a manufacturing method may be modified in various ways other than those shown above.

This application is based on Japanese Patent Application No. 2005-110498 which is hereby incorporated by reference.

What is claimed is:

1. A semiconductor device comprising:
a semiconductor element having a diffusion layer and a gate electrode with a gate insulating film interposed therebetween, the diffusion layer being formed within a silicon layer of an SOI substrate in which the silicon layer is formed on a support substrate with an insulating film interposed therebetween;
a wiring pattern which is formed on an interlayer insulating film covering the silicon layer and is connected to the gate electrode or the diffusion layer of the semiconductor element through a via hole (hereinafter, referred to as ‘via’) penetrating the interlayer insulating film; and
a protection circuit which is connected between the support substrate and the wiring pattern connected to the gate electrode or the diffusion layer and which, when the amount of charges generated with respect to the gate electrode during a plasma process of forming the wiring pattern exceeds a predetermined value, discharges the charges toward the support substrate or blocks the charges.

2. The semiconductor device according to claim 1,
wherein the protection circuit includes a series circuit of a PN junction diode and an NP junction diode each having a breakdown voltage value corresponding to the predetermined value.

3. The semiconductor device according to claim 1,
wherein the protection circuit includes a PNP junction device or an NPN junction device having a breakdown voltage value corresponding to the predetermined value.

4. The semiconductor device according to claim 2,
wherein one of the PN junction diode and the NP junction diode is formed within the silicon layer, and
the other one of the PN junction diode and the NP junction diode is formed by a first conduction-type semiconductor substrate composed of the support substrate and a second conduction-type impurity diffusion layer which is formed within the semiconductor substrate and has a polarity reverse to that of the first conduction-type semiconductor substrate.

5. A semiconductor device comprising:
a semiconductor element having a diffusion layer and a gate electrode with a gate insulating film interposed therebetween, the diffusion layer being formed within a silicon layer of an SOI substrate in which the silicon layer is formed on a support substrate with an insulating film interposed therebetween;
a wiring pattern which is formed on an interlayer insulating film covering the silicon layer and is connected to the gate electrode or the diffusion layer of the semiconductor element through a first via penetrating the interlayer insulating film;
a protection circuit which is connected between the support substrate and the wiring pattern connected to the gate electrode or the diffusion layer and which, when the amount of charges generated with respect to the gate electrode during a plasma process of forming the wiring pattern exceeds a predetermined value, discharges the charges toward the support substrate; and
a dummy conductive pattern which is formed on the interlayer insulating film and is connected to the support substrate through a second via penetrating the interlayer insulating film.

6. The semiconductor device according to claim 5,
wherein the dummy conductive pattern is formed by using one of a plural-dot-shaped conductive pattern, a plate-shaped conductive pattern, and a line-shaped conductive pattern or by a combination of the plural-dot-shaped conductive pattern, the plate-shaped conductive pattern, and the line-shaped conductive pattern.

7. The semiconductor device according to claim 1,
wherein the semiconductor element is a field effect transistor.

8. The semiconductor device according to claim 2,
wherein the semiconductor element is a field effect transistor.

9. The semiconductor device according to claim 3,
wherein the semiconductor element is a field effect transistor.

10. The semiconductor device according to claim 4,
wherein the semiconductor element is a field effect transistor.

11. The semiconductor device according to claim 5,
wherein the semiconductor element is a field effect transistor.

12. The semiconductor device according to claim 6,
wherein the semiconductor element is a field effect transistor.
